(19) United States
(12) Patent Application Publication
(10) Pub. No.: US 2016/0209474 A1
(43) Pub. Date: Jul. 21, 2016

(54) METHOD TO ESTIMATE THE CHARGING TIME OF LITHIUM-ION BATTERIES AND CHARGING MONITOR

(71) Applicant: SIMPLO TECHNOLOGY CO., LTD., Hsinchu County (TW)

(72) Inventors: KUAN-CHENG CHIU, TAIPEI CITY (TW); SHIH-CHOU CHEN, TAOYUAN CITY (TW)

(21) Appl. No.: 14/728,968

(22) Filed: Jun. 2, 2015

(30) Foreign Application Priority Data
Jan. 16, 2015 (TW) 104101499

(51) Int. Cl. G01R 31/36

(52) U.S. Cl. CPC G01R 31/3689; G01R 31/3651

(57) ABSTRACT

The present disclosure provides a method to estimate the charging time of a lithium-ion battery comprising: obtaining a temperature (T), a charging current (Ic) and a charging voltage (V) of the lithium-ion battery during a charging procedure, wherein during the charging procedure the lithium-ion battery is firstly charged in a constant-current charging mode (CC Mode) with a constant-current (I) and then charged in a constant-voltage charging mode (CV Mode); when the lithium-ion battery is charged in the constant-current charging mode, obtaining a constant-current charging time (tcc) and obtaining a constant-voltage full charging time (tcv) in the constant-voltage charging mode according to the temperature, so as to obtain a charging remain time of the lithium-ion battery; and when the lithium-ion battery enters the constant-voltage charge mode, obtaining a constant-voltage charging remain time (tcv′) according to the temperature and the charging current.

### BACKGROUND OF THE INVENTION

1. Field of the Invention

The instant disclosure relates to a lithium-ion battery; in particular, to a method to estimate the charging time of lithium-ion batteries and a charging monitor.

2. Description of Related Art

With advances in technology and the rise of reliance on in technology products, the popularizing rate of electronic products has been increasing rapidly. Because most electronic products (such as the smart phone, the note book, the tablet PC and so on) need to use a battery as their power source, people gradually pay more attention to the status of the batteries of their electronic products. For example, the required exact time of already fully charging the electronic product allows the user to estimate when to unplug the charging connector, for the purpose of avoiding overcharge.

At present, functions of estimating remaining battery power and battery remaining time of commercial electronic products are available. However, the charging behavior of the battery is more complicated compared to discharging behavior, and electronic products having the function of estimating the exact charging remain time of the battery are not currently available in the market.

### SUMMARY OF THE INVENTION

The object of the instant disclosure is to provide an algorithm of estimating the charging time of a lithium-ion battery with a high degree of accuracy and a charging monitor. Several crucial components including but not limited to, temperature, current and voltage are considered in order to achieve accurate estimate of the charging time.

In order to achieve the aforementioned objects, according to an embodiment of the instant disclosure, a method to estimate the charging time of a lithium-ion battery is provided. The method comprises obtaining a temperature (T), a charging current (Ic) and a charging voltage (V) of the lithium-ion battery during a charging procedure, wherein during the charging procedure the lithium-ion battery is firstly charged in a constant-current charging mode (CC Mode) with a constant-current (I) and then charged in a constant-voltage charging mode (CV Mode); when the lithium-ion battery is charged in the constant-current charging mode, obtaining a constant-current charging time (tcc) and obtaining a constant-voltage full charging time (tcv) in the constant-voltage charging mode according to the temperature, wherein a charging remain time of the lithium-ion battery is the constant-current charging time added to the constant-voltage full charging time; and when the lithium-ion battery enters the constant-voltage charge mode, obtaining a constant-voltage charging remain time (tcv′) in the constant-voltage mode according to the temperature and the charging current, wherein the charging remain time of the lithium-ion battery is the constant-voltage charging remain time.

In order to achieve the aforementioned objects, according to an embodiment of the instant disclosure, a charging monitor is provided. The charging monitor is used for monitoring a charging remain time of a lithium-ion battery during a charging procedure, wherein the charging procedure comprising charging in a constant-current charging mode (CC Mode) with a constant-current (I) and then charging in a constant-voltage charging mode (CV Mode). The charging monitor comprises a temperature sensor, a current sensor, a computing unit, a storage unit and a display unit. The temperature sensor senses a temperature (T) of the lithium-ion battery. The current sensor senses a charging current (Ic) of the lithium-ion battery. The computing unit is electrically coupled to the temperature sensor and the current sensor. The computing unit calculates the charging remain time of the lithium-ion battery during the charging procedure. When the lithium-ion battery is charged in the constant-current charging mode, the computing unit obtains a constant-current charging time (tcc) and obtains a constant-voltage full charging time (tcv) in the constant-voltage charging mode according to the temperature, wherein the charging remain time of the lithium-ion battery is the constant-current charging time added to the constant-voltage full charging time. When the lithium-ion battery enters the constant-voltage charge mode, the computing unit obtains a constant-voltage charging remain time (tcv′) according to the temperature and the charging current, wherein the charging remain time is the constant-voltage charging remain time. The storage unit is electrically coupled to the computing unit. The storage unit stores the relationship between the charging current and the constant-voltage charging remain time during the constant-voltage charging mode. The display unit is electrically coupled to the computing unit. The display unit is controlled by the computing unit for displaying the charging remain time of the lithium-ion battery.

In summary, a method to estimate the charging time of a lithium-ion battery and a charging monitor are provided. The method and the monitor considers factors of the battery's chemical property, temperature, amount of charging current, charging mode and battery aging, so as to achieve the purpose of accurately estimating the charging remain time.

In order to further the understanding regarding the instant disclosure, the following embodiments are provided along with illustrations to facilitate the disclosure of the instant disclosure.

### BRIEF DESCRIPTION OF THE DRAWINGS

FIG. 1 shows a current curve diagram of a lithium-ion battery during charging according to an embodiment of the instant disclosure;

FIG. 2 shows a relation curve diagram of the charged capacity X charged to a battery versus the charging current according to an embodiment of the instant disclosure;

FIG. 3 shows a flow chart of a method to estimate the charging time of a lithium-ion battery according to an embodiment of the instant disclosure;

FIG. 4 shows a detailed flow chart of a method to estimate the charging time of a lithium-ion battery according to an embodiment of the instant disclosure;

FIG. 5 shows the calculated charging remain time Te compared with the required actual charging time Tr obtained by an experiment according to an embodiment of the instant disclosure; and

FIG. 6 shows a circuit diagram of a charging monitor according to an embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

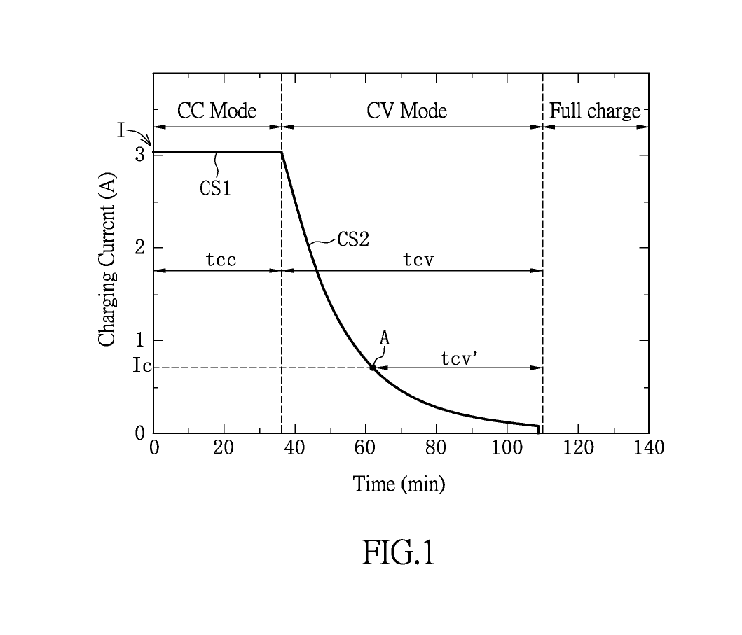

In general, when charging a lithium-ion battery, the conventional charging current curve from constant-current to constant-voltage mode (CC-CV Mode) is illustrated in FIG. 1. When the current sensor senses that the current is flowing towards the battery, it indicates the battery is present at the charging status. At this time, this embodiment uses a computing unit to monitor the charging status of the battery by obtaining the present temperature T, the values of the present current I and the present voltage V of the battery. During the charging procedure, the lithium-ion battery is firstly charged in a constant-current charging mode (CC Mode) with a constant-current (I), referred to as the current curve CS1 charging in constant-current shown in FIG. 1, wherein in this embodiment, the provided example of the constant current I represents 1C charging current (or so called the 1C charging rate), but the instant disclosure is not so restricted. Although we can obtain a different charging curve of current corresponding to a different value of the constant current I, we would use the same principle for calculating the remaining charging time.

After the constant-current charging mode (CC Mode), the lithium-ion battery is then charged in a constant-voltage charging mode (CV Mode). The charging current of the constant-voltage charging mode (CV mode) of this embodiment is indicated as Ic, referred to as the current curve CS2 charging in constant-voltage shown in FIG. 1. At the same temperature, for the same lithium-ion battery, when the constant charging current I in the constant-current charging mode (CC Mode) is known, the current curve CS2 charging in constant-voltage would be determined according to the aforementioned charging modes. During the whole charging procedure, the charging time of the constant-current charging mode (CC Mode) is indicated as the constant-current charging time tcc. The charging time of the constant-voltage charging mode (CV mode) is indicated as the constant-voltage full charging time tcv. The charged capacity of the lithium-ion battery is the charging current (Ic) integrated over time t, that is the total area under the curve CS1 and the curve CS2 is the total charged capacity of the lithium-ion battery.

At different temperatures, the current curve generated by charging in the constant-voltage charging mode (CV mode) is different. Also, the internal status of the lithium-ion battery varies depending on the difference of the finished charging/discharging procedures (for example, different charging/discharging rates) in the past. Although the time point switching to the constant-voltage mode (CV Mode) is different when the lithium-ion battery with different remaining capacity is charged by the same initial charging current (constant current I) at the same temperature, the slopes of current curves CS2 charging in constant-voltage are the same. In other words, when executing the mentioned charging procedure comprising the constant-current charging mode (CC Mode) and the constant-voltage charging mode (CV mode) by the same initial charging current (which is the constant current) I at the same temperature, there is only one kind of corresponding current curve CS2 charging in constant-voltage regardless of the remaining battery power before the charge. That is, when the temperature T and the initial charging current (which is the constant current) I are known, the current curve CS2 charging in constant-voltage can be determined accordingly. For the remaining battery power difference, shift the current curve CS2 charging in constant-voltage depending on the time point of changing the charging mode from CC Mode to CV mode. Also, when the specification of the lithium-ion battery is known, the rated capacity (FCC) of the lithium-ion battery can be obtained. On the condition that the constant-voltage charging curves of current CS2 is determined, the constant-voltage full charging time (tcv) can be determined.

In practical applications, the current curve CS2 charging in constant-voltage can be pre-stored in a manner of a look-up table or a function. In this paragraph, the method of obtaining the constant-voltage charging remain time (tcv′) is described first. In order to simplify the calculation, select multiple points at the current curve CS2 charging in constant-voltage for storing to the look-up table. That is, according to the stored look-up table, each charging current located at the current curve CS2 charging in constant-voltage has a corresponding constant-voltage charging remain time. For example, the charging current of the point A in FIG. 1 is Ic, and the corresponding constant-voltage charging remain time is tcv′ illustrated in FIG. 1. The computing unit can obtain the required constant-voltage charging remain time tcv′ in the constant-voltage charging mode (CV mode) according to the present charging current Ic and the present temperature T by the way of looking-up the table. Based on the information of the battery's chemical property, the constant-voltage charging look-up table is created and stored in a storage unit in advance. The format and the content of the constant-voltage charging look-up table can be seen in the table below.

| | | T (deg C.) | | | | |
|---|---|---|---|---|---|---|
| tcv′ (s) | | 10 | 17 | 25 | 35 | 45 |
| Ic | 0.02 | tcv′_{0.02, 10} | | [symbol] | | tcv′_{0.02, 45} |
| (C-Rate) | 0.06 | | | | | |
| | 0.1 | | [symbol] | | [symbol] | |
| | 0.15 | | | | | |
| | 0.2 | [symbol] | | tcv′ₘₙ | | [symbol] |
| | 0.3 | | | | | |
| | 0.5 | | [symbol] | | [symbol] | |
| | 1 | | | | | |
| | 1.2 | tcv′_{1.2, 10} | | [symbol] | | tcv′_{1.2, 45} |

For example, as shown in the table, when the temperature of the battery is at constant T=25 degC (t), then n=25 according to the table; when the charging current is 0.25C, then, in the table, m=0.25. If the measured present temperature T and the present charging current Ic is not stored in the constant-voltage charging look-up table, utilize interpolation or extrapolation with the constant-voltage charging look-up table to calculate the constant-voltage charging remain time tcv′ corresponding to the present temperature T and the present charging current Ic. Compared to the constant-voltage charging remain time tcv′, the constant-voltage full charging time tcv can be treated as a special case of the constant-voltage charging remain time tcv′, thus the constant-voltage full charging time tcv can also be stored in the look-up table.

The mentioned interpolation and extrapolation can be carried out by a variety of calculation algorithms, and the instant disclosure is not so restricted. Taking the linear interpolation as an example, in order to calculate tcv when T=25 degC, and charging current I=0.25C, the detailed embodiment is described in the following:

Assume a coordinate point is tcv′ 0.2, 25=1000 (which is the value of tcv′ when T=25 degC and T=0.2C) listed in the prestored table, and another point tcv′ 0.3, 25=2000 (which is the value of tcv′ when T=25 degC and T=0.3C), taking these two points into the following equation to obtain tcv′ 0.25, 25 (which is the value of tcv′ when T=25 degC and T=0.25C):

$$\begin{matrix}{tcv}_{0.25 , 25}^{′} = {tvc}_{0.2}^{′} , 25 + ( {tcv}_{0.3 , 2.5}^{′} - {tcv}_{0.25 , 25}^{′} ) \frac{( {I}_{0.25} - {I}_{0.2} )}{( {I}_{0.3} - {I}_{0.2} )} \\ = 1000 + ( 2000 - 1000 ) \frac{( 0.25 - 0.2 )}{( 0.3 - 0.2 )} \\ = 1500\end{matrix}$$

Referring to FIG. 1 again, when current curves CS2 charging in constant-voltage at each temperature T are well known, the constant-voltage full charging time (tcv) can be determined, and the total amount of charge (the area under the curve CS2) in the constant-voltage charging mode (CV Mode) can be determined. Then, use the computing unit to perform integrating the charging current (constant current I) over time t, in order to obtain the electric capacity charged to the battery in the constant-voltage charging mode (CV Mode), which can be indicated as charged capacity X, and X would be stored to the storage unit (memory, for example). Calculation of the X can be made by using the following equation:

X=∫Idt;

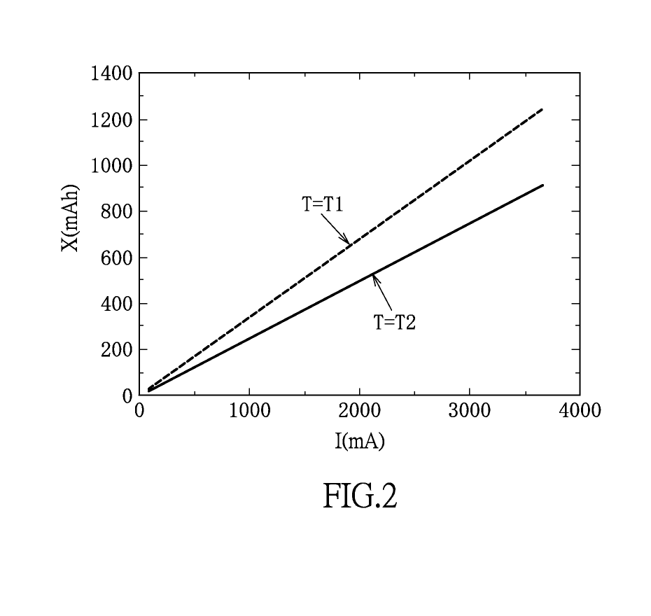

According to practical measurement for the charging procedure of the lithium-ion battery, and due to the electrochemical properties of the battery, the relation between the current I and the charged capacity X can be obtained as shown in FIG. 2 which shows that the charged capacity X is a function of the constant current I. In one embodiment, the relation between I and X can be approximated by a straight line passing through the origin and with a slope pcv, X=pcv*I. Thus, the calculation can be simplified. In other words, each temperature corresponds to a straight line with its slope pcv. For example, as shown in FIG. 2, temperature T1 and temperature T2 respectively corresponds to a straight line with different slope. In the constant-voltage charging mode (CV Mode), the charged capacity X and the slope pcv corresponding to each temperature T can be stored by using a charged capacity look-up table. That is, when the temperature T and the present charging current (constant current I) are known, the charged capacity look-up table can be used to obtain the slope pcv, for obtaining the charged capacity X accordingly.

As mentioned above, for the approximated expression (X=pcv*I) of the charged capacity X in the constant-voltage charging mode (CV Mode), the slope pcv will be changed due to the variation of the temperature T. Therefore, based on the present temperature, use the implemented charging current (which is the constant current I) to find out the slope pcv by the method of looking-up the table, so as to obtain the charged capacity X. Then, calculating the constant-current charging time tcc:

tcc=(RC/I)−pcv;

wherein RC is an electric capacity to be charged to the battery from the present time to the time of already fully charging the battery, which is the rated capacity of the battery (FCC) minus the charged capacity X:

RC=FCC−X.

Then, the remaining charging time Te is the constant-current charging time tcc added to the constant-voltage full charging time (tcv), that is Te=tcc+tcv.

Additionally, if there is no temperature value stored in the charged capacity look-up table corresponding to the present temperature T, the calculation method of interpolation or extrapolation can be used to calculate the value of the slope pcv.

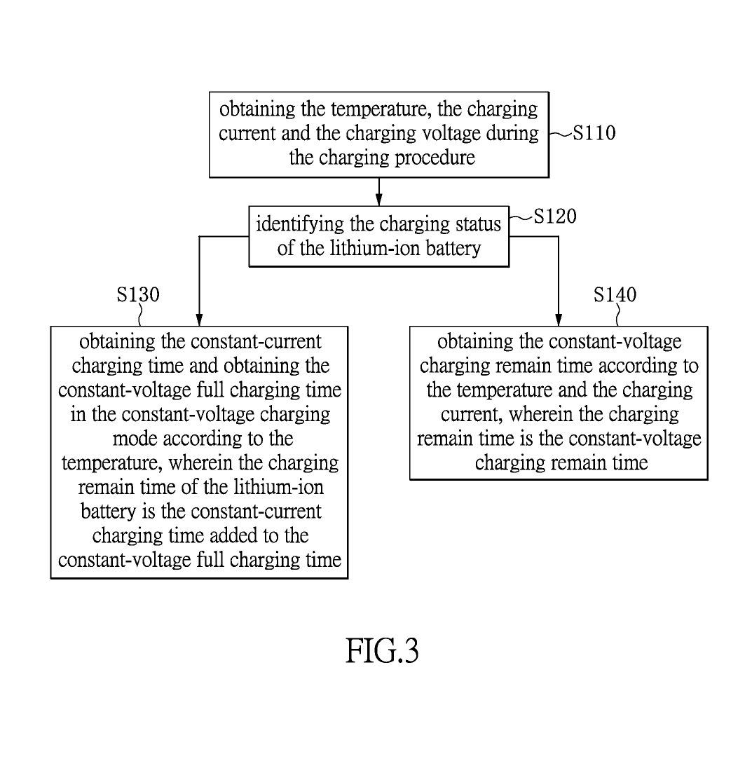

Next, the flow of the method to estimate the remaining charging time of the lithium-ion battery of this embodiment will be described. Please refer to FIG. 3. FIG. 3 shows a flow chart of a method to estimate the charging time of a lithium-ion battery according to an embodiment of the instant disclosure. The method comprises the following steps. Step S110, sampling (or obtaining) the temperature T, the charging current Ic and a charging voltage V of the lithium-ion battery during the charging procedure. Then, executing step S120, determining the charging status of the lithium-ion battery, and executing step S130 or S140 according to the determination result.

When the lithium-ion battery is charged in the constant-current charging mode, executing step S130, obtaining the constant-current charging time tcc and obtaining the constant-voltage full charging time tcv in the constant-voltage charging mode according to the temperature, wherein the charging remain time of the lithium-ion battery is the constant-current charging time added to the constant-voltage full charging time.

In detail, if the lithium-ion battery has not yet entered the constant-voltage charging mode (CV Mode), then it (the computing unit) needs to obtain the constant-current charging time (tcc) and the constant-voltage full charging time (tcv), and add the constant-current charging time (tcc) and the constant-voltage full charging time (tcv), so as to obtain the estimated charging remain time. On the other hand, if the computing unit determines that the charging mode has already entered the constant-voltage charging mode (CV Mode), then the constant-current charging time tcc=0 in the constant-current charging mode (CC Mode) can be obtained, and then the obtained constant-voltage charging remain time (tcv′) would be the charging remain time.

Based on the above, in order to obtain the constant-current charging time (tcc) in the constant-current charging mode (CC Mode), the detailed implementation of step S130 can be: obtaining a charged capacity of the lithium-ion battery charged in the constant-voltage charging mode at the temperature T, wherein the charged capacity is approximated by the relation equation X=pcv*I, and a corresponding charged capacity look-up table is established accordingly, wherein X is the charged capacity, pcv is a slope, I is the constant current; then, utilizing the constant current to find out the slope pcv according to the charged capacity look-up table; and calculating the constant-current charging time according to the slope by using the following equations,

RC=FCC−X;

tcc=(RC/I−pcv);

wherein RC is an electric capacity to be charged to the lithium-ion battery from the present time to the time of already fully charging the lithium-ion battery, tcc is the constant-current charging time, FCC is a rated capacity of the lithium-ion battery.

On the other hand, when the lithium-ion battery enters the constant-voltage charging mode, executing step S140, obtaining the constant-voltage charging remain time tcv′ in the constant-voltage mode according to the present temperature and the present charging current, wherein the charging remain time is the constant-voltage charging remain time tcv′.

In detail, each temperature T corresponds to a current curve CS2 charging in constant-voltage and the current curve CS2 charging in constant-voltage corresponds to the constant-voltage full charging time tcv. In one embodiment, the method of obtaining the constant-voltage charging remain time tcv′ in the constant-voltage mode can be: obtaining the current curve CS2 (as shown in FIG. 1) charged in constant-voltage of the lithium-ion battery in the constant-voltage charging mode (CV Mode) at the temperature T; and obtaining the constant-voltage charging remain time tcv′ according to the current curve CS2 charging in constant-voltage and the charging current Ic.

However, directly using the current curve CS2 charging in constant-voltage to perform the calculation has higher calculation costs. In order to simplify the complexity of the calculation, the current curve CS2 charging in constant-voltage can be stored by using a look-up table. That is, using a look-up table to store the charging current Ic and the constant-voltage charging remain time tcv′ which correspond to a plurality of points at the current curve CS2 charging in constant-voltage shown in FIG. 1, so as to establish the look-up tables of constant-voltage charging mode (CV mode) at a variety of temperatures. And, utilizing the look-up table to find out the constant-voltage charging remain time tcv′ corresponding to the present temperature T and the present charging current Ic.

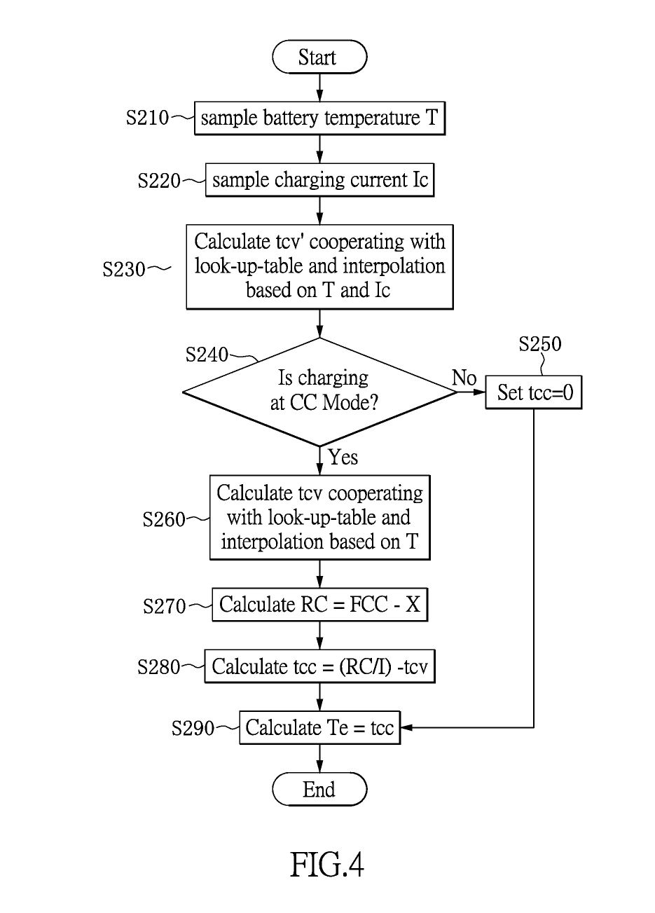

As mentioned above, in practical applications, in the manner of cooperating with the look-up table, the scheme of the flow shown in FIG. 3 can be implemented by the flow chart shown in FIG. 4. At first, in step S210 and step S220, respectively sampling the temperature T and the charging current Ic. Then, in step S230, calculating the constant-voltage charging remain time tcv′ cooperating with the look-up-table and interpolation based on the temperature T and the charging current Ic. Then, executing step S240, determining whether it is at the constant-current charging mode (CC Mode). If not, it indicates that the charging procedure has entered the constant-voltage mode (CV Mode), and executing step S250, setting tcc as zero, and executing step S290, calculating Te=tcc+tcv.

If the charging procedure is still in the constant-current charging mode (CC Mode), executing step S260, calculating the constant-voltage full charging time tcv cooperating with the look-up-table and interpolation based on the temperature T. Then, executing step S270, calculating RC=FCC−X. Then, executing step S280, calculating tcc=(RC/I)−pcv. Then, executing step S290.

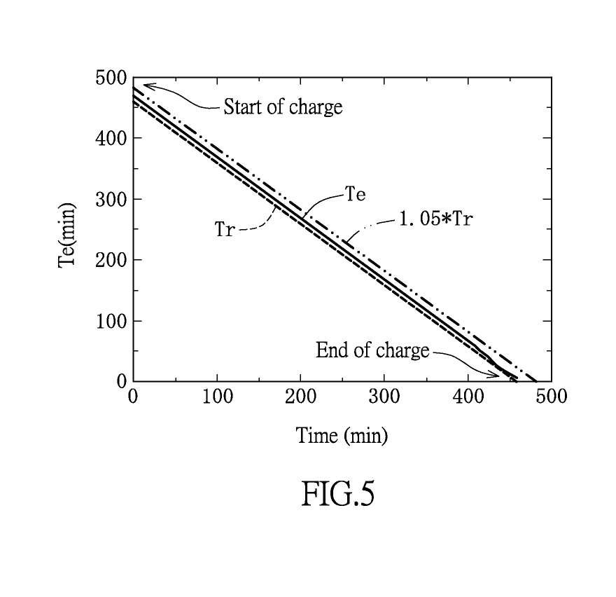

According to the flow chart of FIG. 4, the summation of the constant-current charging tcc and the constant-voltage full charging time tcv is the battery's charging remain time Te=tcc+tcv. Comparison between the battery's charging remain time Te and the required actual charging time Tr based on experiment result is shown in FIG. 5. In FIG. 5, it can be seen that the value of Te estimated by the method of estimation can be located within the error range of 0%˜+5%, from the start of charge until the end of charge. If there is an error exceeding the range of 0%˜+5% between the estimated value of Te and the value of the required actual charging time Tr, an error correction value E can be added to/or subtracted from the value of Te at the next time of charge, for achieving the purpose of limiting the errors between 0%˜+5%. A specific embodiment is described in the following:

Te=tcc+tcv+E;

if the value of Te is less than the value of Tr by j minutes, then E=j; if the value of Te is higher than 1.05 times of the value of Tr by k minutes, then E=−k. However, the instant disclosure is not so restricted. The manner related to error correction can be modified according to practical applications.

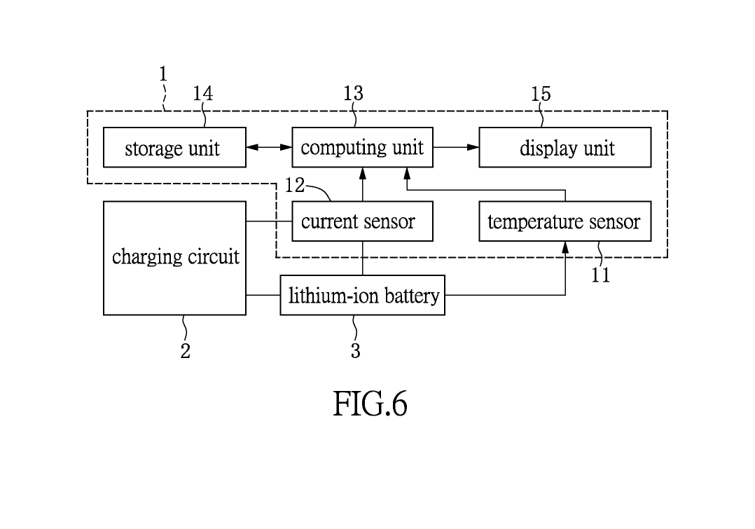

Please refer to FIG. 6. FIG. 6 shows a circuit diagram of a charging monitor according to an embodiment of the instant disclosure. A charging circuit 2 is used for charging a lithium-ion battery 3, wherein the charging procedure comprises charging in the constant-current charging mode (CC Mode) with the constant-current (I) and then charging in the constant-voltage charging mode (CV Mode). Accordingly, the charging circuit 2 can comprise, a control circuit, a constant current source, a voltage converter, a voltage sensor, a current sensor, and so on, for example, in order to control and drive the charging current and the charging voltage. However, this instant disclosure does not limit the implementation of the charging circuit 2, and an artisan of ordinary skill in the art will appreciate the design of the corresponding circuit. Relatively, a charging monitor 1 is used for monitoring a charging remain time of a lithium-ion battery during the charging procedure. The charging monitor 1 comprises a temperature sensor 11, a current sensor 13, a computing unit 13, a storage unit 14 and a display unit 15. The temperature sensor 11 senses the temperature (T) of the lithium-ion battery 3. The current sensor 12 senses the charging current (Ic) of the lithium-ion battery 3. The computing unit 13 is electrically coupled with the temperature sensor 11 and the current sensor 12, the storage unit 14 and the display unit 15. The computing unit 13 calculates the charging remain time of the lithium-ion battery 3 during the charging procedure. When the lithium-ion battery 3 is charged in the constant-current charging mode, the computing unit 13 obtains the constant-current charging time (tcc) and obtains the constant-voltage full charging time (tcv) in the constant-voltage charging mode according to the temperature, wherein the charging remain time of the lithium-ion battery 3 is the constant-current charging time added to the constant-voltage full charging time. When the lithium-ion battery 3 enters the constant-voltage charge mode, the computing unit 13 obtains the constant-voltage charging remain time (tcv′) according to the temperature and the charging current, wherein the charging remain time is the constant-voltage charging remain time. The storage unit 14 stores the relationship between the charging current and the constant-voltage charging remain time during the constant-voltage charging mode. The display unit 15 is controlled by the computing unit 13 for displaying the charging remain time of the lithium-ion battery.

The relationship between the charging current and the constant-voltage charging remain time stored in the storage unit 14 is the current curve charging in constant-voltage or a constant-voltage charging look-up table. According to the aforementioned embodiment, the current curve charging in constant-voltage and the constant-voltage charging look-up table are used to calculate the constant-voltage charging remain time corresponding the present temperature and the present charging current. When the storage unit 14 stores the current curve charging in constant-voltage, and when the present temperature and the present charging current is not stored in the constant-voltage charging look-up table, utilizing interpolation or extrapolation with the constant-voltage charging look-up table to obtain the constant-voltage charging remain time corresponding to the present temperature and the present charging current.

Further, the storage unit 14 stores the information of the charged capacity (X) of the lithium-ion battery charged in the constant-voltage charging mode at certain temperatures, the information of the charged capacity is presented by a function (X=pcv*I) of the constant current or a charged capacity look-up table.

In one embodiment, the charging monitor can also comprise a voltage sensor. The voltage sensor is electrically coupled to the lithium-ion battery for sensing the charging voltage, and the voltage sensor is coupled to the computing unit 13. For example, the computing unit 13 can obtain the charging status (constant-current charging mode or constant-voltage charging mode) of the lithium-ion battery 3 through the current status sensed by the current sensor 12 or the voltage status sensed by the voltage sensor. Alternatively, the computing unit 13 can also directly obtain the charging status of the lithium-ion battery 3 from the charging circuit 2. The computing unit 13 computes (or calculates) the detailed information of the charging remain time of the lithium-ion battery, referring to the description of the aforementioned embodiment, and the redundant information is not repeated.

According to above description, the provided method to estimate the charging time of the lithium-ion battery and the charging monitor in the instant disclosure considers factors of the battery's chemical properties, temperature, amount of charging current, charging mode and battery aging, so as to achieve the purpose of accurately estimating the charging remain time. As the experiment confirmed, the error of the estimated result can be within 0%˜5%, for solving the issue of too large error. Additionally, in order to simplify the complexity of the calculation, the instant disclosure also provides storing the related functions as look-up tables, so as to save the calculation costs.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

What is claimed is:

1. A method to estimate the charging time of a lithium-ion battery comprising:
obtaining a temperature (T), a charging current (Ic) and a charging voltage (V) of the lithium-ion battery during a charging procedure, wherein during the charging procedure the lithium-ion battery is firstly charged in a constant-current charging mode (CC Mode) with a constant-current (I) and then charged in a constant-voltage charging mode (CV Mode);
when the lithium-ion battery is charged in the constant-current charging mode, obtaining a constant-current charging time (tcc) and obtaining a constant-voltage full charging time (tcv) in the constant-voltage charging mode according to the temperature, wherein a charging remain time of the lithium-ion battery is the constant-current charging time added to the constant-voltage full charging time; and
when the lithium-ion battery enters the constant-voltage charge mode, obtaining a constant-voltage charging remain time (tcv′) in the constant-voltage mode according to the temperature and the charging current, wherein the charging remain time of the lithium-ion battery is the constant-voltage charging remain time.

2. The method to estimate the charging time of the lithium-ion battery according to claim 1, wherein in the step of when the lithium-ion battery is charged in the constant-current charging mode obtaining the constant-voltage full charging time (tcv) in the constant-voltage charging mode according to the temperature, the temperature corresponds to a current curve charging in constant-voltage (CV curve), the current curve charging in constant-voltage corresponds to the constant-voltage full charging time.

3. The method to estimate the charging time of the lithium-ion battery according to claim 1, wherein in the step of obtaining the constant-voltage charging remain time (tcv′) in the constant-voltage charge mode, establishing a constant-voltage charging look-up table, utilizing the constant-voltage charging look-up table to find out the constant-voltage charging remain time corresponding to the present temperature and the present charging current.

4. The method to estimate the charging time of the lithium-ion battery according to claim 3, wherein when the present temperature and the present charging current is not stored in the constant-voltage charging look-up table, utilizing interpolation or extrapolation with the constant-voltage charging look-up table to calculate the constant-voltage charging remain time (tcv′) corresponding to the present temperature and the present charging current.

5. The method to estimate the charging time of the lithium-ion battery according to claim 1, wherein the step of obtaining the constant-voltage charging remain time (tcv′) in the constant-voltage mode comprises:
obtaining a current curve charging in constant-voltage of the lithium-ion battery in the constant-voltage charging mode at the temperature; and
obtaining the constant-voltage charging remain time (tcv′) according to the current curve charging in constant-voltage and the charging current.

6. The method to estimate the charging time of the lithium-ion battery according to claim 1, wherein the step of obtaining the constant-current charging time (tcc) in the constant-voltage charging mode comprises:
obtaining a charged capacity of the lithium-ion battery charged in the constant-voltage charging mode at the temperature, wherein the charged capacity is approximated by the relation equation X=pcv*I, and a corresponding charged capacity look-up table is established accordingly, wherein pcv is a slope, I is the constant current;
utilizing the constant current to find out the slope according to the charged capacity look-up table; and
calculating the constant-current charging time according to the slope by using the following equations,
RC=FCC−X;
tcc=(RC/I−pcv);
wherein RC is an electric capacity to be charged to the lithium-ion battery from the present time to the time of already fully charging the lithium-ion battery, tcc is the constant-current charging time, FCC is a rated capacity of the lithium-ion battery.

7. A charging monitor, used for monitoring a charging remain time of a lithium-ion battery during a charging procedure, the charging procedure comprising charging in a constant-current charging mode (CC Mode) with a constant-current (I) and then charging in a constant-voltage charging mode (CV Mode), the charging monitor comprising:
a temperature sensor, sensing a temperature (T) of the lithium-ion battery;
a current sensor, sensing a charging current (Ic) of the lithium-ion battery;
a computing unit, electrically coupling with the temperature sensor and the current sensor, the computing unit calculating the charging remain time of the lithium-ion battery during the charging procedure;
wherein when the lithium-ion battery is charged in the constant-current charging mode, the computing unit obtaining a constant-current charging time (tcc) and obtaining a constant-voltage full charging time (tcv) in the constant-voltage charging mode according to the temperature, wherein the charging remain time of the lithium-ion battery is the constant-current charging time added to the constant-voltage full charging time;
when the lithium-ion battery enters the constant-voltage charge mode, the computing unit obtaining a constant-voltage charging remain time (tcv′) according to the temperature and the charging current, wherein the charging remain time is the constant-voltage charging remain time;
a storage unit, electrically coupling to the computing unit, the storage unit storing the relationship between the charging current and the constant-voltage charging remain time during the constant-voltage charging mode; and
a display unit, electrically coupling to the computing unit, the display unit controlled by the computing unit for displaying the charging remain time of the lithium-ion battery.

8. The charging monitor according to claim 7, wherein the relationship between the charging current and the constant-voltage charging remain time (tcv′) stored in the storage unit is a current curve charging in constant-voltage, the current curve charging in constant-voltage is used to calculate the constant-voltage charging remain time (tcv′) corresponding the present temperature and the present charging current.

9. The charging monitor according to claim 7, wherein the storage unit stores the charging current and the constant-voltage charging remain time (tcv′) as a constant-voltage charging look-up table, the constant-voltage charging look-up table is used to find out the constant-voltage charging remain time (tcv′) corresponding to the present temperature and the present charging current.

10. The charging monitor according to claim 9, wherein when the present temperature and the present charging current is not stored in the constant-voltage charging look-up table, utilizing interpolation or extrapolation with the constant-voltage charging look-up table to obtain the constant-voltage charging remain (tcv′) time corresponding to the present temperature and the present charging current.

11. The charging monitor according to claim 7, wherein the storage unit stores the information of a charged capacity (X) of the lithium-ion battery charged in the constant-voltage charging mode at the temperature, the information of the charged capacity is presented by a function of the constant current or a charged capacity look-up table.

12. The charging monitor according to claim 7, wherein the computing unit calculates the constant-current charging time (tcc) by following steps:
obtaining a charged capacity of the lithium-ion battery charged in the constant-voltage charging mode at the temperature, wherein the charged capacity is approximated by the relation equation X=pcv*I, and a corresponding charged capacity look-up table is established accordingly, wherein X is the charged capacity, pcv is a slope, I is the constant current;
utilizing the constant current to find out the slope according to the charged capacity look-up table; and
calculating the constant-current charging time according to the slope by using the following equations,
RC=FCC−X;
tcc=(RC/I−pcv);
wherein RC is an electric capacity to be charged to the lithium-ion battery from the present time to the time of already fully charging the lithium-ion battery, tcc is the constant-current charging time, FCC is a rated capacity of the lithium-ion battery.
